(19) United States
(12) Patent Application Publication
(10) Pub. No.: US 2010/0044821 A1
(43) Pub. Date: Feb. 25, 2010

(54) SEMICONDUCTOR DEVICE AND MANUFACTURING METHOD THEREOF

(75) Inventors: Takashi Noma, Ota-shi (JP); Yoshimasa Amatatsu, Ora-gun (JP); Yoshinori Seki, Ora-gun (JP); Hiroyuki Shinogi, Gifu (JP)

Correspondence Address: MORRISON & FOERSTER LLP, 1650 TYSONS BOULEVARD, SUITE 400, MCLEAN, VA, 22102, US

(73) Assignees: SANYO Electric Co., Ltd., Moriguchi-shi (JP); SANYO Semiconductor Co., Ltd., Ora-gun (JP)

(21) Appl. No.: 12/538,304

(22) Filed: Aug. 10, 2009

(30) Foreign Application Priority Data
Aug. 25, 2008 (JP) 2008-215000

(51) Int. Cl. H01L 31/0216; H01L 31/18

(52) U.S. Cl. 257/435; 438/70; 257/E31.121; 257/E21.211

(57) ABSTRACT

This invention offers a semiconductor device to measure a luminance for the visible wavelength range of light components and its manufacturing method which reduce its manufacturing cost. A first light-receiving element and a second light-receiving element are formed in a semiconductor substrate. Then, there is formed an arithmetic circuit that calculates a difference between a value of an electric current corresponding to an amount of light detected by the first light-receiving element (that is, a value of an electric current representing a relative sensitivity against the light) and a value of an electric current corresponding to an amount of light detected by the second light-receiving element (that is, a value of an electric current representing a relative sensitivity against the light). Next, a first green pass filter permeable only to light in a green wavelength range and an infrared wavelength range is formed to cover the first light-receiving element, while a second green pass filter similar to the first green filter is formed to cover the second light-receiving element. In addition, a red pass filter permeable only to light in a red wavelength range and the infrared wavelength range is formed to cover the second light-receiving element.

This application claims priority from Japanese Patent Application No. 2008-215000, the content of which is incorporated herein by reference in its entirety.

### BACKGROUND OF THE INVENTION

1. Field of the Invention

This invention relates to a semiconductor device and its manufacturing method, specifically to a semiconductor device provided with a light-receiving element and its manufacturing method.

2. Description of the Related Art

A CSP (Chip Size Package) has received attention in recent years as a new packaging technology. The CSP means a small package having about the same outside dimensions as those of a semiconductor die packaged in it.

An illuminance sensor provided with a light-receiving element has been known as one of products packaged in the CSP. The illuminance sensor is incorporated in a wide variety of electronic equipment. When it is incorporated in a mobile phone, for example, it is used to measure a luminance of a visible wavelength range of light components of external light as a reference for adjusting luminance of a display panel and turning on/off of lighting of a keyboard.

An example of a structure of the illuminance sensor is described hereafter. A light-receiving element 113 such as a photo diode is disposed on a top surface of a semiconductor substrate 10 constituting the illuminance sensor, and an insulation film 114 is disposed to cover it, as shown in FIG. 10. In addition, a supporter 117 provided with an infrared cut filter 116 that removes light components in an infrared wavelength range is bonded to the top surface of the semiconductor substrate 10 through an adhesive layer 115. The supporter 117 extends beyond an edge of the semiconductor substrate 10. Pad electrodes 118 electrically connected with the light-receiving element 113 are disposed on portions of the supporter 117 extended beyond the edge of the semiconductor substrate 10. The pad electrodes 118 are covered with the insulation film 114. An insulation film 119 is disposed on a back surface of the semiconductor substrate 10, and a wiring 120 connected with the pad electrode 118 through an opening in the insulation film 119 extends over the back surface of the semiconductor substrate 10.

Furthermore, a protection film 121 is disposed to cover the wiring 120, and bump electrodes 122, each connected with the wiring 120 through an opening formed in the protection film 121, are disposed on the back surface of the semiconductor substrate 10.

With the illuminance sensor, the luminance can be measured only for light components in the visible wavelength range included in the external light by removing the light components in the infrared wavelength range with the infrared cut filter 116 from the external light incident on the light-receiving element 113.

The CSP incorporating the light-receiving element covered with the infrared cut filter is described in Japanese Patent Application Publication No. 2004-200966, for example.

However, the infrared cut filter 116 constituting the illuminance sensor causes an increase in the manufacturing cost, since it is a so-called interference type infrared cut filter that is formed by many times of vapor deposition of metal such as titanium oxide, which is not included in an ordinary semiconductor manufacturing process to form a semiconductor device.

In order to cope with it, it is conceivable that a resin including fine bits of metal such as titanium oxide is formed to cover the light-receiving element 113 as a material to cut the infrared radiation, instead of bonding the supporter 117 provided with the infrared cut filter 116. However, there is a problem that a reduction rate of the infrared radiation by the material is only about 50% of the reduction rate by the interference type infrared cut filter 116.

### SUMMARY OF THE INVENTION

The invention provides a semiconductor device that includes a semiconductor substrate, a first light-receiving element and a second light-receiving element formed in the semiconductor substrate, a first optical color resist covering the first and second light-receiving elements, a second optical color resist covering only the second light-receiving element, an arithmetic circuit calculating a difference between a value of an electric output corresponding to an amount of light detected by the first light-receiving element and a value of an electric output corresponding to an amount of light detected by the second light-receiving element. The first optical color resist allows light transmission only in a green wavelength range and an infrared wavelength range, and the second optical color resist allows light transmission only in a red wavelength range and the infrared wavelength range.

The invention also provides a semiconductor device that includes a semiconductor substrate, a first light-receiving element and a second light-receiving element formed in the semiconductor substrate, a supporter bonded to the semiconductor substrate through an adhesive layer so that the supporter covers the first and second light-receiving elements, a first optical color resist formed on the supporter so as to cover the first and second light-receiving elements, a second optical color resist formed on the semiconductor substrate so as to cover only the second light-receiving element, and an arithmetic circuit calculating a difference between a value of an electric output corresponding to an amount of light detected by the first light-receiving element and a value of an electric output corresponding to an amount of light detected by the second light-receiving element. The first optical color resist allows light transmission only in a green wavelength range and an infrared wavelength range, and the second optical color resist allows light transmission only in a red wavelength range and the infrared wavelength range.

The invention further provides a method of manufacturing a semiconductor device. The method includes providing a semiconductor substrate, forming a first light-receiving element and a second light-receiving element in the semiconductor substrate, forming in the semiconductor substrate an arithmetic circuit calculating a difference between a value of an electric output corresponding to an amount of light detected by the first light-receiving element and a value of an electric output corresponding to an amount of light detected by the second light-receiving element, forming a first optical color resist so as to cover the first and second light-receiving elements, and forming a second optical color resist so as to cover only the second light-receiving element. The first optical color resist allows light transmission only in a green wavelength range and an infrared wavelength range, and the second optical color resist allows light transmission only in a red wavelength range and the infrared wavelength range.

The invention also provides a method of manufacturing a semiconductor device. The method includes providing a supporter having a first optical color resist formed on the supporter, providing a semiconductor substrate, forming a first light-receiving element and a second light-receiving element in the semiconductor substrate, forming in the semiconductor substrate an arithmetic circuit calculating a difference between a value of an electric output corresponding to an amount of light detected by the first light-receiving element and a value of an electric output corresponding to an amount of light detected by the second light-receiving element, forming a second optical color resist on the semiconductor substrate so as to cover only the second light-receiving element, and bonding the supporter to the semiconductor substrate through an adhesive layer so that the first optical color resist covers the first and second light-receiving elements. The first optical color resist allows light transmission only in a green wavelength range and an infrared wavelength range, and the second optical color resist allows light transmission only in a red wavelength range and the infrared wavelength range.

### BRIEF DESCRIPTION OF THE DRAWINGS

FIG. 1 is a cross-sectional view showing a semiconductor device and its manufacturing method according to a first embodiment of this invention.

FIG. 2 is a cross-sectional view showing the semiconductor device and its manufacturing method according to the first embodiment of this invention.

FIG. 3 is a plan view showing the semiconductor device and its manufacturing method according to the first embodiment of this invention.

FIG. 4 is a graph showing a correlation between a relative sensitivity and a wavelength.

FIG. 5 is a graph showing a correlation between the relative sensitivity and the wavelength.

FIG. 6 is a graph showing a correlation between the relative sensitivity and the wavelength.

FIG. 7 is a graph showing a correlation between the relative sensitivity and the wavelength.

FIG. 8 is a cross-sectional view showing a semiconductor device and its manufacturing method according to a second embodiment of this invention.

FIG. 9 is a cross-sectional view showing a semiconductor device and its manufacturing method according to a third embodiment of this invention.

FIG. 10 is a cross-sectional view showing a conventional semiconductor device.

### DETAILED DESCRIPTION OF THE INVENTION

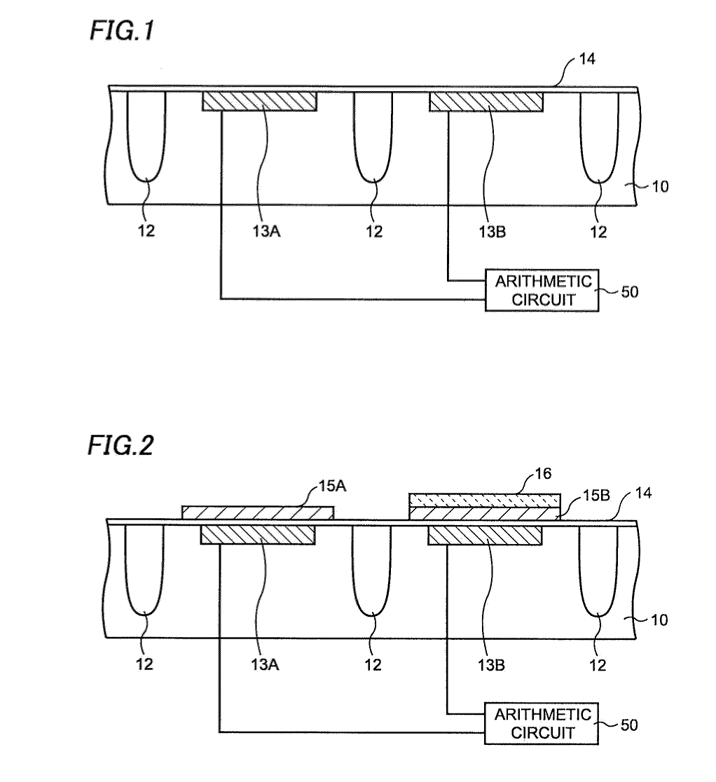

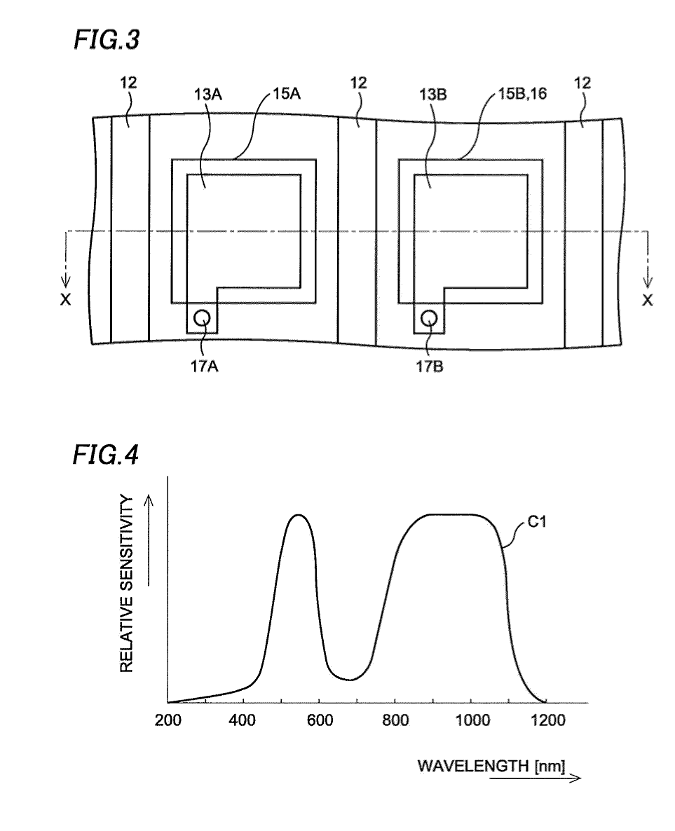

A semiconductor device and its manufacturing method according to a first embodiment of this invention will be described hereafter referring to the drawings. FIGS. 1 and 2 are cross-sectional views showing the semiconductor device and its manufacturing method according to the first embodiment. They show a region of a semiconductor substrate 10 where one of the semiconductor devices is to be formed out of the semiconductor substrate 10 in a wafer form in which a plurality of the semiconductor devices is to be formed. FIG. 3 is a plan view showing the semiconductor device according to the first embodiment. The cross-sectional views shown in FIGS. 1 and 2 correspond to a section X-X in FIG. 3.

First, the semiconductor substrate 10 made of single crystalline silicon of P⁺ type, for example, is provided as shown in FIG. 1. An undoped semiconductor layer is epitaxially grown on the semiconductor substrate 10. Device isolation layers 12 of P⁺ type, for example, are formed so that the semiconductor layer is separated into a plurality of element forming regions. The undoped semiconductor layer is hereafter described as it is included in the semiconductor substrate 10, and is not depicted separately from the semiconductor substrate 10 in the drawings.

A first light-receiving element 13A consisting of a photo diode is formed in a surface of the semiconductor layer in one of the element forming regions, while a second light-receiving element 13B consisting of a photo diode is formed in a surface of another of the element forming regions. One each of the light-receiving elements, the first light-receiving element 13A and the second light-receiving element 13B, is formed in a region where one of the semiconductor devices is to be formed. However, this invention is not limited to the above, and a plurality of each of the light-receiving elements may be formed in the region.

In order to form the first light-receiving element 13A and the second light-receiving element 13B, an N⁺ type layer is formed by doping a surface region of the undoped semiconductor layer in the semiconductor substrate 10 with N type impurities such as phosphorus (P), so that a surface of the N⁺ type layer serves as a light-receptive surface, for example. An insulation film 14 such as a silicon oxide film is formed by CVD (Chemical Vapor Deposition), for example, to cover the first light-receiving element 13A and the second light-receiving element 13B.

An arithmetic circuit 50 connected with the first light-receiving element 13A and the second light-receiving element 13B is formed in the region in the semiconductor substrate 10, where the one of the semiconductor devices is to be formed. The arithmetic circuit 50 includes electronic devices such as transistors, and calculates a difference between a value of an electric current corresponding to an amount of light detected by the first light-receiving element 13A (that is, a value of an electric current representing a relative sensitivity against the light) and a value of an electric current corresponding to an amount of light detected by the second light-receiving element 13B (that is, a value of an electric current representing a relative sensitivity against the light). The arithmetic circuit 50 may be formed of an analog subtracter or a combination of A/D converters and a digital arithmetic unit, for example.

Next, a first green pass filter 15A is formed on the insulation film 14 so as to cover the first light-receiving element 13A, while a second green pass filter 15B is formed on the insulation film 14 so as to cover the second light-receiving element 13B, as shown in FIGS. 2 and 3.

The first green pass filter 15A and the second green pass filter 15B are made of a first optical color resist that allows light transmittance only in a green wavelength range and an infrared wavelength range out of external light incident on them. The first optical color resist includes a pigment dispersed in an organic resin, which makes a so-called OCF (Optical Color Filter) used as a color filter for a liquid crystal display device and the like.

After the first optical resist is applied all over the insulation film 14, the first green pass filter 15A and the second green pass filter 15B are formed preferably spaced from each other as shown in the drawing, by removing unnecessary portions by photolithography or the like, in order to reserve a region to form an electrode and the like in subsequent process steps. If the region is considered not to be required in the subsequent process steps, the first green pass filter 15A and the second green pass filter 15B may be formed all over the insulation film 14 without separation.

After that, a red pass filter 16 is formed to cover the second green pass filter 15B that is formed to cover the second light-receiving element 13B. The red pass filter 16 covers the second light-receiving element 13B, but does not cover the first light-receiving element 13A. The red pass filter 16 is made of a second optical color resist that allows light transmission only in a red wavelength range and the infrared wavelength range out of the external light incident on it. The second optical color resist includes a pigment dispersed in an organic resin, which makes a so-called OCF used as a color filter for a liquid crystal display device and the like.

In the structure described above, note that the green wavelength range is included in a range between 500 nm and 600 nm, the red wavelength range is included in a range between 600 nm and 700 nm, and the infrared wavelength range is included in a range between 700 nm and 1200 nm, for example.

Next, an electrode 17A, that is to make a cathode electrode or an anode electrode, is formed on a portion of the first light-receiving element 13A extending beyond the first green pass filter 15A as shown in FIG. 3, when it is required. Similarly, an electrode 17B, that is to make a cathode electrode or an anode electrode, is formed on a portion of the second light-receiving element 13B extending beyond the second green pass filter 15B and the red pass filter 16. After process steps that are required, a stacked body made of the semiconductor substrate 10 and layers stacked on it is subject to dicing.

Although not shown in the drawings, a pad electrode connected with the first light-receiving element 13A, a pad electrode connected with the second light-receiving element 13B, a wiring connected with each of the pad electrodes and extending over a back surface of the semiconductor substrate 10 through an insulation film, a protection film covering the wiring, a bump electrode connected with the wiring through an opening in the protection film and the like may be formed in the process steps described above. Those structures may be the same structures as exemplified by the pad electrode 118, the insulation film 119, the wiring 120, the protection film 121 and the bump electrode 122, as shown in FIG. 10.

An example of how the first light-receiving element 13A and the second light-receiving element 13B in the semiconductor device are used as the illuminance sensor is described hereafter. FIGS. 4 through 7 are graphs showing correlations between a relative sensitivity for each light component of each wavelength and each wavelength of light component detected by the first light-receiving element 13A and the second light-receiving element 13B. The vertical axis of the graphs represents the relative sensitivity, while the horizontal axis represents the wavelength in nm. The relative sensitivity denotes a ratio of an electric current flowing through the first light-receiving element 13A or the second light-receiving element 13B when light is detected by each of them to the maximum value of the electric current.

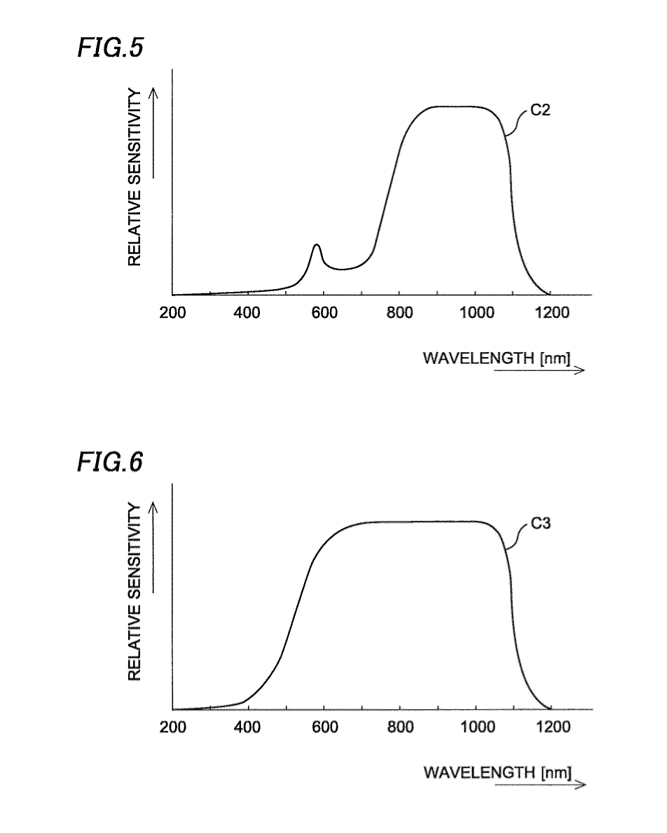

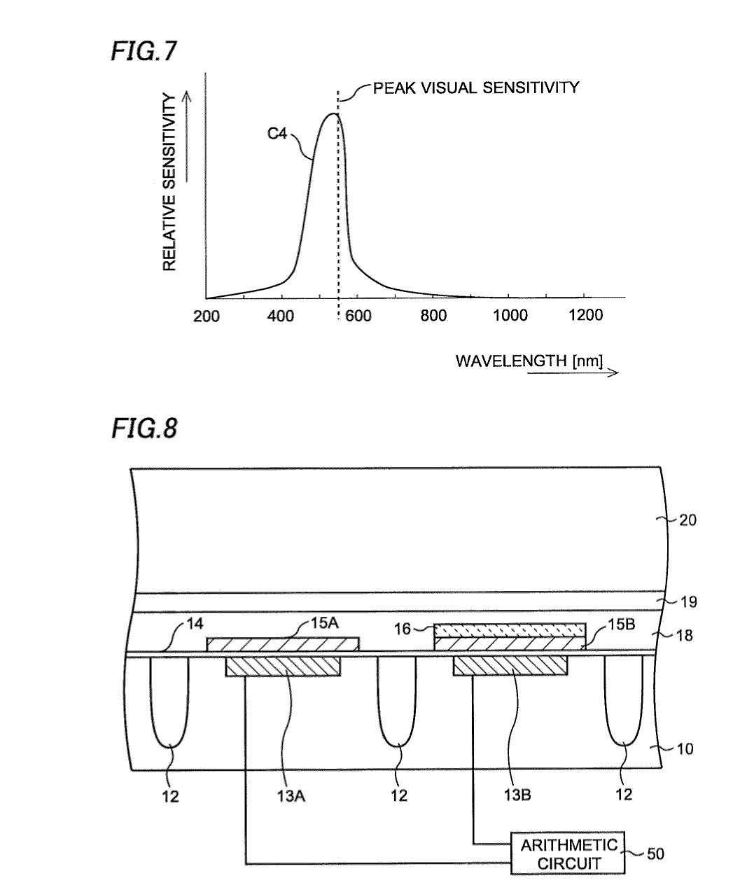

A curve C1 shown in FIG. 4 represents the relative sensitivity for the light component detected by the first light-receiving element 13A through the first green pass filter 15A. A curve C2 shown in FIG. 5 represents the relative sensitivity for the light component detected by the second light-receiving element 13B through the second green pass filter 15B and the red pass filter 16. A curve C3 shown in FIG. 6 is a reference example showing the relative sensitivity in a hypothetical case in which light component traveled only through the red pass filter 16 would be detected by the second light-receiving element 13B. A curve C4 shown in FIG. 7 represents a difference between the relative sensitivity represented as the curve C1 and the relative sensitivity represented as the curve C2. It should be noted that the curves C1, C2, C3 and C4 are not to be regarded as representing precise values of the relative sensitivity and the wavelength, and to be regarded as schematically showing their features for the sake of the explanation.

The curves C1, C2, C3 and C4 show that light components in a wavelength range between 200 nm and 1200 nm are detected and that no light component out of the range is detected. Also, they show that very small amount of light components is detected in a wavelength range around 200 nm and in a wavelength range around 1200 nm. This is because absorption of light by silicon included in layers forming the first light-receiving element 13A and the second light-receiving element 13B hardly occurs for the light component of the wavelength shorter than 200 nm and the light component of the wavelength longer than 1200 nm, so that no or very small amount of electric current is caused for the light components of those wavelength ranges.

As seen from the curve C1 in FIG. 4, the first light-receiving element 13A detects light components having two peaks, one in the green wavelength range and one in the infrared wavelength range. As seen from the curve C2 in FIG. 5, on the other hand, the second light-receiving element 13B detects light components having a peak in the infrared wavelength range, albeit with a faint peak in the green wavelength range. The feature of the curve C2 is a synthesis of the feature shown by the curve C1 in FIG. 4 and the feature shown by the curve C3 in FIG. 6. That is, the feature of the curve C2 is obtained by limiting the wavelength range of light components of the external light travelling through the red pass filter 16 and further limiting the wavelength range of the light components travelling through the second green pass filter 15B.

And the curve C4 is obtained by calculating with the arithmetic circuit 50 the difference between the electric current corresponding to the light detected by the first light-receiving element 13A, which represents the relative sensitivity shown by the curve C1, and the electric current corresponding to the light detected by the second light-receiving element 13B, which represents the relative sensitivity shown by the curve C2, as shown in FIG. 7. The curve C4 is close enough to be regarded as equivalent to visibility characteristics of human being, which have peak visual sensitivity at around 550 nm and provide the relative sensitivity in a wavelength range between about 500 nm and about 600 nm, although a peak of the curve C4 is a little closer to a shorter wavelength side than the peak visual sensitivity of human being. In other words, the luminance can be measured only for the visible wavelength range of the light components included in the external light incident on the first light-receiving element 13A and the second light-receiving element 13B

Also, measuring the luminance only for the visible wavelength range of the light components included in the external light does not require the infrared cut filter that is required in the conventional art and increases the manufacturing cost. Instead, the first green pass filter 15A, the second green pass filter 15B and the red pass filter 16 are provided. Increase in the manufacturing cost of the semiconductor device can be suppressed since these filters are formed using the optical color resist that is inexpensive and easy to form.

Also, the low reduction rate of the infrared radiation by the material used in the conventional art is no longer a problem, since the light components in the infrared wavelength range are not removed, and instead the light components are detected by the first light-receiving element 13A and the second light-receiving element 13B through the optical color resist and the relative sensitivity of the light components in the visible wavelength range is calculated with the arithmetic circuit 50 based on the results of the detection.

Furthermore, as seen from the curve C2 in FIG. 5, the light incident on the second light-receiving element 13B through the red pass filter 16 and the second green pass filter 15B is practically made of the light components in the infrared wavelength range, since it has a peak in the infrared wavelength range as a whole. That is, the second light-receiving element 13B can be used as an infrared sensor by itself. On the other hand, the first light-receiving element 13A, the second light-receiving element 13B and the arithmetic circuit 50 can be used as the illuminance sensor to measure the luminance for the visible wavelength range of the light components by working in concert with each other.

A proximity sensor that requires detecting light components in the infrared wavelength range may be named as one of appropriate usage of the second light receiving element 13B as an infrared sensor, for example. That is, the semiconductor device has the function of the illuminance sensor as well as the function of the proximity sensor.

Although the second green pass filter 15B and the red pass filter 16 are stacked on the second light-receiving element 13B in the order as described, this invention is not limited to the above, and the red pass filter 16 may be formed first followed by forming the second green pass filter 15B thereupon. The effects described above can be obtained in this case also.

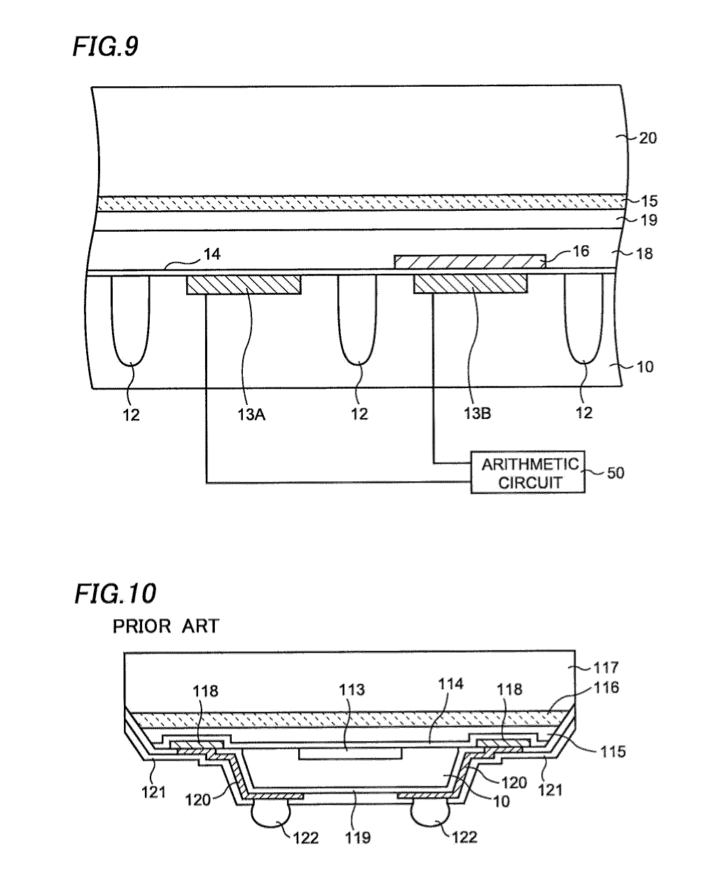

The semiconductor device according to the first embodiment described above may have a structure as a chip size package. This case is described hereafter as a second embodiment and a third embodiment of this invention. FIGS. 8 and 9 are cross-sectional views, each showing a semiconductor device according to the second embodiment and a semiconductor device according to the third embodiment of this invention, respectively.

First, the second embodiment is explained. In the second embodiment, an interlayer insulation film 18 such as a silicon oxide film is formed on the insulation film 14 so as to cover the first green pass filter 15A, the second green pass filter 15B and the red pass filter 16, as shown in FIG. 8, in addition to the structure according to the first embodiment as shown in FIG. 2. Each of the electrodes 17A and 17B connected to each of the first and second light-receiving elements 13A and 13B, respectively, is formed in a contact hole provided in the interlayer insulation film 18 and extends over a surface of the interlayer insulation film 18, although they are not shown in the drawing.

Next, a supporter 20 is bonded to the interlayer insulation film 18 on the semiconductor substrate 10 through an adhesive layer 19. The supporter 20 is made of a transparent or semitransparent material, such as a glass substrate or a plastic. The other structural features and process steps are similar to those in the first embodiment. The same effects as in the first embodiment are obtained in the second embodiment.

Next, the third embodiment is explained. In the third embodiment, a single green pass filter 15 is formed on the supporter 20 as shown in FIG. 9 instead of the first and second green pass filters 15A and 15B that are formed on the semiconductor substrate 10 in the second embodiment. The green pass filter 15 is formed on one of surfaces of the supporter 20 so as to cover at least regions overlapping the first light-receiving element 13A and the second light-receiving element 13B. FIG. 9 shows the case in which the green pass filter 15 is formed on all of one of the surfaces of the supporter 20, that is, the surface facing the semiconductor substrate 10. On the other hand, the red pass filter 16 is formed on the insulation film 14 on the semiconductor substrate 10 to cover the second light-receiving element 13B.

In this case, the green pass filter 15 may be formed on the supporter 20 before the supporter 20 is bonded to the semiconductor substrate 10, and the supporter 20 with green pass filter 15 may be bonded to the semiconductor substrate 10 afterward. The other structural features and process steps are similar to those in the first embodiment. The same effects as in the first embodiment are obtained in the third embodiment.

In addition, the semiconductor devices having the structure providing the effects equivalent to those obtained in the embodiment can be manufactured more effectively according to the process steps as described above, since a large number of the supporters 20, on each of which the green pass filter is formed, can be pre-manufactured to be stored.

This invention is not limited to the embodiments described above and may be modified within the scope of the invention.

For example, a blue pass filter made of an optical color resist that allows light transmission only in a blue wavelength range and the infrared wavelength range may be formed instead of the first green pass filter 15A, the second green pass filter 15B or the green pass filter 15 in each of the embodiments described above, although it is not shown in the drawings. In this case, the second light-receiving element 13B can be used by itself as an infrared sensor based on the principle as described above, although its characteristic is not as good as one described in the embodiments. On the other hand, the first light-receiving element 13A, the second light-receiving element 13B and the arithmetic circuit 50 can be used as the illuminance sensor to measure the luminance for the visible wavelength range of the light components based on the principle as described above. It is noted that the light component measured in this case has a peak in the blue wavelength range as a whole, and that the usage of the sensor is to measure the light component in the blue wavelength range.

Also, although it is stated that the semiconductor device according to the embodiments described above may include the same structures as exemplified by the pad electrode 118, the insulation film 119, the wiring 120, the protection film 121 and the bump electrode 122 as shown in FIG. 10, it may include structures other than those described above. For example, there may be formed a via hole extending from the back surface of the semiconductor substrate 10 to the pad electrode which is formed on the semiconductor substrate 10, and a through-hole electrode connected with the pad electrode through the via hole and extending over the back surface of the semiconductor substrate 10, although they are not shown in the drawings.

Also, although the single chip of the semiconductor device is provided with the first light-receiving element 13A, the second light-receiving element 13B and the arithmetic circuit 50 according to the embodiments described above, this invention is not limited to the above. That is, although not shown in the drawing, the first light-receiving element 13A, the second light-receiving element 13B and the arithmetic circuit 50 in the first embodiment may be formed separately each as a bare chip or a combination of two of them as a bare chip. The first green pass filter 15A, the second green pass filter 15B and the red pass filter 16 are formed in a bare chip, in which the first light-receiving element 13A and the second light-receiving element 13B are formed, as described above. In this case, each of the bare chips may be used by itself, or may be mounted in a single package.

According to this invention, measuring the luminance for the visible wavelength range of light components included in the external light does not require the infrared cut filter that increases the manufacturing cost. Because the optical color resist that can be formed easily and less expensively is used instead, the increase in the manufacturing cost can be suppressed.

Also, the low reduction rate of the infrared radiation by the material used in the conventional art is no longer a problem, since the light components in the infrared wavelength range are detected by the first light-receiving element and the second light-receiving element through the optical color resist and the relative sensitivity of the light components in the visible wavelength range is calculated with the arithmetic circuit based on the results of the detection.

Also, the light incident on the second light-receiving element through the first optical color resist and the second optical color resist is practically made of the light component in the infrared wavelength range. That is, the second light-receiving element can be used as an infrared sensor by itself. On the other hand, the first light-receiving element, the second light-receiving element and the arithmetic circuit can be used as the illuminance sensor to measure the luminance for the visible wavelength range of the light components by working in concert with each other.

What is claimed is:

1. A semiconductor device comprising:
a semiconductor substrate;
a first light-receiving element and a second light-receiving element formed in the semiconductor substrate;
a first optical color resist covering the first and second light-receiving elements, the first optical color resist allowing light transmission only in a green wavelength range and an infrared wavelength range;
a second optical color resist covering only the second light-receiving element, the second optical color resist allowing light transmission only in a red wavelength range and the infrared wavelength range; and
an arithmetic circuit calculating a difference between a value of an electric output corresponding to an amount of light detected by the first light-receiving element and a value of an electric output corresponding to an amount of light detected by the second light-receiving element.

2. The semiconductor device of claim 1, further comprising a supporter bonded to the semiconductor substrate through an adhesive layer so that the supporter covers the first and second light-receiving elements.

3. The semiconductor device of claim 1, wherein the green wavelength range comprises a wavelength range between 500 nm and 600 nm, the red wavelength range comprises a wavelength range between 600 nm and 700 nm, and the infrared wavelength range comprises a wavelength range between 700 nm and 1200 nm.

4. The semiconductor device of claim 2, wherein the green wavelength range comprises a wavelength range between 500 nm and 600 nm, the red wavelength range comprises a wavelength range between 600 nm and 700 nm, and the infrared wavelength range comprises a wavelength range between 700 nm and 1200 nm.

5. A semiconductor device comprising:
a semiconductor substrate;
a first light-receiving element and a second light-receiving element formed in the semiconductor substrate;
a supporter bonded to the semiconductor substrate through an adhesive layer so that the supporter covers the first and second light-receiving elements;
a first optical color resist formed on the supporter so as to cover the first and second light-receiving elements, the first optical color resist allowing light transmission only in a green wavelength range and an infrared wavelength range;
a second optical color resist formed on the semiconductor substrate so as to cover only the second light-receiving element, the second optical color resist allowing light transmission only in a red wavelength range and the infrared wavelength range; and
an arithmetic circuit calculating a difference between a value of an electric output corresponding to an amount of light detected by the first light-receiving element and a value of an electric output corresponding to an amount of light detected by the second light-receiving element.

6. The semiconductor device of claim 5, wherein the green wavelength range comprises a wavelength range between 500 nm and 600 nm, the red wavelength range comprises a wavelength range between 600 nm and 700 nm, and the infrared wavelength range comprises a wavelength range between 700 nm and 1200 nm.

7. A method of manufacturing a semiconductor device, comprising:
providing a semiconductor substrate;
forming a first light-receiving element and a second light-receiving element in the semiconductor substrate;
forming in the semiconductor substrate an arithmetic circuit calculating a difference between a value of an electric output corresponding to an amount of light detected by the first light-receiving element and a value of an electric output corresponding to an amount of light detected by the second light-receiving element;
forming a first optical color resist so as to cover the first and second light-receiving elements, the first optical color resist allowing light transmission only in a green wavelength range and an infrared wavelength range; and
forming a second optical color resist so as to cover only the second light-receiving element, the second optical color resist allowing light transmission only in a red wavelength range and the infrared wavelength range.

8. The method of claim 7, further comprising bonding a supporter to the semiconductor substrate through an adhesive layer so that the supporter covers the first and second light-receiving elements.

9. The method of claim 7, wherein the green wavelength range comprises a wavelength range between 500 nm and 600 nm, the red wavelength range comprises a wavelength range between 600 nm and 700 nm, and the infrared wavelength range comprises a wavelength range between 700 nm and 1200 nm.

10. The method of claim 8, wherein the green wavelength range comprises a wavelength range between 500 nm and 600 nm, the red wavelength range comprises a wavelength range between 600 nm and 700 nm, and the infrared wavelength range comprises a wavelength range between 700 nm and 1200 mm.

11. A method of manufacturing a semiconductor device comprising:
providing a supporter comprising a first optical color resist formed on the supporter, the first optical color resist allowing light transmission only in a green wavelength range and an infrared wavelength range;
providing a semiconductor substrate;
forming a first light-receiving element and a second light-receiving element in the semiconductor substrate;
forming in the semiconductor substrate an arithmetic circuit calculating a difference between a value of an electric output corresponding to an amount of light detected by the first light-receiving element and a value of an electric output corresponding to an amount of light detected by the second light-receiving element;
forming a second optical color resist on the semiconductor substrate so as to cover only the second light-receiving element, the second optical color resist allowing light transmission only in a red wavelength range and the infrared wavelength range; and
bonding the supporter to the semiconductor substrate through an adhesive layer so that the first optical color resist covers the first and second light-receiving elements.

12. The method of claim 11, wherein the green wavelength range comprises a wavelength range between 500 nm and 600 nm, the red wavelength range comprises a wavelength range between 600 nm and 700 nm, and the infrared wavelength range comprises a wavelength range between 700 nm and 1200 nm.
